(19) United States
(12) Patent Application Publication
(10) Pub. No.: US 2016/0049434 A1
(43) Pub. Date: Feb. 18, 2016

(54) DIGITAL RADIATION SENSOR PACKAGE

(71) Applicant: Excelitas Technologies Singapore PTE Ltd., Singapore (SG)

(72) Inventors: Arthur John Barlow, Alton (GB); Anand Pandy, Roxboro (CA)

(21) Appl. No.: 14/458,433

(22) Filed: Aug. 13, 2014

(51) Int. Cl. H01L 27/146; H01L 31/0232; H01L 31/02

(52) U.S. Cl. CPC H01L 27/14634; H01L 31/02005; H01L 31/02327

(57) ABSTRACT

A radiation sensing apparatus includes, in a vertically stacked configuration: a radiation sensor chip, an integrated circuit chip beneath the radiation sensor chip, and an optical element above the radiation sensor chip. The radiation sensor chip has a radiation sensing element and an electrically-conductive contact coupled to the radiation sensing element and exposed at a lower surface. The integrated circuit chip has an integrated circuit and an electrical conductor coupled to the integrated circuit and exposed at an upper surface. The electrically conductive contact at the lower surface of the radiation sensor chip is physically and electrically coupled to the electrical conductor at the upper surface of the integrated circuit chip. The optical element is configured to pass incident radiation at a wavelength that the radiation sensing element is configured to sense.

### FIELD OF THE INVENTION

This disclosure relates to a digital radiation sensor package and, more particularly, relates to a digital radiation sensor package that includes, in a stacked configuration, a radiation sensor chip, an integrated circuit chip beneath the radiation sensor chip, and an optical element above the radiation sensor chip.

### BACKGROUND

There are various radiation sensing technologies. Thermopiles, for example, convert thermal energy into electrical energy. Typically, a thermopile includes several thermocouples connected together, usually in series. Photodiodes, as another example, convert light into electrical energy. There are also various packaging designs available for radiation sensing technologies. There remains a need, however, for compact, high performance packaging designs.

### SUMMARY OF THE INVENTION

In one aspect, a radiation sensing apparatus includes, in a vertically stacked configuration: a radiation sensor chip, an integrated circuit chip beneath the radiation sensor chip, and an optical element above the radiation sensor chip. The radiation sensor chip has a radiation sensing element and an electrically-conductive contact coupled to the radiation sensing element and exposed at a lower surface. The integrated circuit chip has an integrated circuit and an electrical conductor coupled to the integrated circuit and exposed at an upper surface. The electrically conductive contact at the lower surface of the radiation sensor chip is physically and electrically coupled to the electrical conductor at the upper surface of the integrated circuit chip. The optical element is configured to pass incident radiation at a wavelength that the radiation sensing element is configured to sense.

In another aspect, a method of manufacturing a radiation sensing apparatus is disclosed. The apparatus includes, in a vertically stacked configuration, an integrated circuit chip, a radiation sensor chip, and an optical element. The method includes providing a radiation sensor chip having a radiation sensing element and an electrically conductive contact coupled to the radiation sensing element and exposed at a lower surface of the radiation sensor chip. The radiation sensor chip is coupled to the integrated circuit chip beneath the radiation sensor chip. The integrated circuit chip has an integrated circuit and an electrical conductor coupled to the integrated circuit and exposed at an upper surface of the integrated circuit chip facing the lower surface of the radiation sensor chip. The radiation sensor chip is coupled to an optical element above the radiation sensor chip. The optical element is configured to pass incident radiation at a wavelength that the radiation sensing element is configured to sense. Coupling the radiation sensor chip to the integrated circuit chip includes physically and electrically coupling the electrically conductive contact at the lower surface of the radiation sensor to the electrical conductor at the upper surface of the integrated circuit chip.

In some implementations, one or more of the following advantages are present.

For example, in a typical implementation, the techniques and structures disclosed herein enable providing a simple, small, inexpensive, overall package design that provides a high degree of performance capability, particularly as compared to conventional surface mount technology designs. These techniques and structures may be applied advantageously in a variety of applications including, for example, in mobile electronics platforms, where volume and height, in particular, are paramount, yet a high performance is still required or at least highly desirable.

Some implementations, for example ones that utilize thermopiles, can be used in connection with software applications to facilitate skin measurements of a user making a phone call, ambient temperature measurements (e.g., objects may be cold or hot) and, a wake-up trigger based on proximity of a human. Some implementations, for example ones that utilize photodiodes, can be used to facilitate miniature gesture sensing (e.g., using a light-emitting diode to illuminate the area to be sensed. Use of multiple pixels (e.g., two or four) can facilitate position or directional sensing.

In a typical implementation, the techniques and structures disclosed herein facilitate a small overall package volume without compromising the sensor's active (sensing) area, which greatly affects its sensitivity, and yet still allow a reasonable area for application specific integrated circuitry on its chip, to permit higher-end sensor signal processing algorithms to be run within the ASIC controller circuits.

Other features and advantages will be apparent from the description and drawings, and from the claims.

### BRIEF DESCRIPTION OF THE DRAWINGS

FIG. 1A is a schematic side view of a radiation sensor assembly.

FIG. 1B is a cutaway plan view of the radiation sensor assembly in FIG. 1A.

FIG. 2A is a schematic side view of a radiation sensor assembly.

FIG. 2B is a cutaway plan view of the radiation sensor assembly in FIG. 2A.

FIG. 3A is a schematic side view of a radiation sensor assembly.

FIG. 3B is a cutaway plan view of the radiation sensor assembly in FIG. 3A.

FIG. 4A is a schematic side view of a radiation sensor assembly.

FIG. 4B is a cutaway plan view of the radiation sensor assembly in FIG. 4A.

FIG. 5A is a schematic side view of a radiation sensor assembly.

FIG. 5B is a cutaway plan view of the radiation sensor assembly in FIG. 5A.

FIG. 6A is a schematic side view of a radiation sensor assembly.

FIG. 6B is a cutaway plan view of the radiation sensor assembly in FIG. 6A.

FIG. 7A is a schematic side view of a radiation sensor assembly.

FIG. 7B is a cutaway plan view of the radiation sensor assembly in FIG. 7A.

FIG. 8A is a schematic side view of a radiation sensor assembly.

FIG. 8B is a cutaway plan view of the radiation sensor assembly in FIG. 8A.

FIG. 9 is a series of schematic, cross-sectional views showing a radiation sensing apparatus at various stages of manufacture.

FIG. 10 is a series of schematic, cross-sectional views showing a radiation sensing apparatus at various stages of manufacture.

FIG. 11 is a series of schematic, cross-sectional views showing a radiation sensing apparatus at various stages of manufacture.

FIG. 12 is a series of schematic, cross-sectional views showing a radiation sensing apparatus at various stages of manufacture.

FIG. 13 is a series of schematic, cross-sectional views showing a radiation sensing apparatus at various stages of manufacture.

FIG. 14 is a schematic cross-sectional view of an exemplary integrated circuit chip with dimensions shown in millimeters.

Like reference numerals refer to like elements.

### DETAILED DESCRIPTION

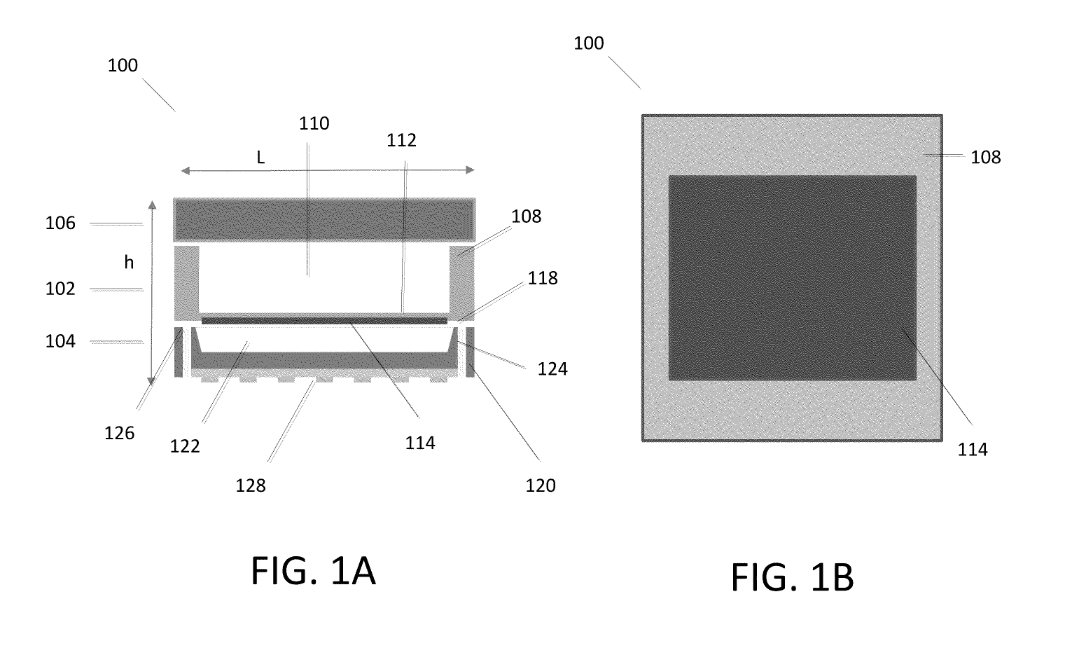

FIG. 1A show a radiation sensor assembly 100 that includes, in a stacked configuration, a radiation sensor chip 102 (e.g., one that includes a single thermopile), an integrated circuit chip 104 beneath the radiation sensor chip 102 and an optical element 106 above the radiation sensor chip 102. In the illustrated implementation, the radiation sensor chip 102, the integrated circuit chip 104 and the optical element 106 are substantially aligned with each other in a vertical direction. More particularly, the radiation sensor chip 102 and the integrated circuit chip 104 are aligned to facilitate a direct electrical connection between those components in a stacked configuration. Additionally, the radiation sensor chip 102 and the optical element 106 are aligned to ensure that the radiation sensing elements will be properly positioned relative to the optical axis of the assembly 100 to ensure proper sensing functionality. In the particular example shown, the respective outer edges of the illustrated components are in alignment with each other as well.

In a typical implementation, this stacked configuration, and other stacked configurations, such as those described elsewhere herein, provides a simple, compact and inexpensive sensor assembly design. Moreover, in a typical implementation, the sensor design provides a high degree of performance capability due, in part, to the large surface area available to accommodate radiation sensing elements and/or due, in part, to the large amount of space available to accommodate integrated circuitry, which can, as a result of the large amount of space be designed to support complex signal processing and interfacing functionalities.

Furthermore, in a typical implementation, the concepts disclosed herein provide a low-height package, all digital output, infrared or near infrared sensor. In a typical implementation, the height (“h”) in FIG. 1A, for example, or thickness of the overall package is about 1.0 millimeters (e.g., between about 0.6 mm and 1.4 mm, or between about 0.9 mm and 1.1 mm). There is an option to include multiple sensing elements (e.g., two, three, four or more) in the sensor to facilitate gesture, movement, temperature and proximity measurements. This technology may be particularly desirable in mobile electronics platforms, where volume and height, in particular, are paramount, but high levels of performance are still required.

The radiation sensor chip 102 is centrally disposed between the integrated circuit chip 104 and the optical element 106. The radiation sensor chip 102 is able to sense radiation and deliver an electrical signal to the integrated circuit chip 104 that represents the sensed radiation.

The radiation sensor chip 102 has a substrate 108 that defines a centrally-disposed opening 110 that extends through part of the substrate 108 and a membrane 112 that extends across the centrally-disposed opening 110 at the bottom of the opening 110. The opening is typically sized to maximize the sensor area (i.e., the area at the bottom of the opening where the radiation-sensing element(s) receives radiation. In some implementations, the total length (“L” in the figure) of the sensor assembly 100 is about 1.0 mm (e.g., between about 0.8 mm and 1.6 mm) and the width of the opening 110 is about 0.7 mm (e.g., between about 0.5 mm and 1.3 mm, or between about 0.6 mm and 0.8 mm).

The substrate 108 of the radiation sensor chip 102 can be virtually any type of material. Typically, the substrate should be a material that can provide an adequate degree of structural rigidity in the thicker wall sections 116 of the substrate 108 and also provide some degree of thermal isolation for the radiation sensing elements 114 on the bottom surface of the thinner membrane 112 section of the substrate 108. In some implementations, the substrate 108 of the radiation sensor chip 102 is silicon. The membrane should be at least substantially transmissive to whatever wavelength(s) of radiation the radiation sensing element 114 is designed to sense. If the radiation sensing element is an infrared sensor, for example, then the radiation to be sensed may include wavelengths from about 700 nanometers to about 1000 microns. If the radiation sensing element is a photodiode, for example, then the radiation to be sensed may be from about 0.2 microns to about 3.5 microns.

There is a radiation-sensing element 114 on a bottom surface of the membrane 112. The radiation-sensing element 114 can be virtually any kind of radiation sensing element. For example, in some implementations, the radiation-sensing element 114 is a thermopile. In general, a thermopile is an electronic device that converts thermal energy into electrical energy. It is generally composed of several thermocouples electrically connected usually in series or, less commonly, in parallel, to produce a single direct current (DC) output. As another example, in some implementations, the radiation-sensing element 114 is a photodiode. In general, a photodiode is a semiconductor diode that, when exposed to light, generates a potential difference or changes its electrical resistance. In some implementations, the radiation-sensor element 114 can includes multiple thermopiles, photodiodes, etc. connected together in series and/or parallel with each other. In some implementations, there may be an additional infra-red absorbing layer included integrally under the active sensing element 114 (not shown). This absorbing layer will absorb the infra-red radiation entering the optical elements 106, traversing the membrane 118 and sensing element 114. The radiation absorbed will raise the temperature of the sensing element 114 and thereby induce the output signal in relation to the incoming radiation.

In the illustrated implementation, the radiation-sensing element 114 is configured to produce an output voltage that corresponds to an amount of radiation sensed by the radiation sensing element 114. The radiation-sensing element 114 is electrically coupled to a pair of electrically-conductive output contacts 118 at a bottom surface of the radiation sensor chip 102 facing the integrated circuit chip 104. Each electrically-conductive output contacts 118 is near an outer edge of the bottom surface of the substrate 108. During operation, the output voltage from the radiation-sensing elements appears across the electrically-conductive output contacts 118.

In a typical implementation, the radiation sensor chip 102 has an overall thickness (i.e., from top to bottom in the illustrated example) of about 0.4 millimeters (e.g., from about 0.3 mm to about 0.5 mm, or from about 0.35 mm to about 0.45 mm).

The integrated circuit chip 104 is beneath the radiation sensor chip 102. The integrated circuit chip 104 is able to process electrical signals it receives from the radiation sensor chip 102 and interface with external circuitry (not shown).

The integrated circuit chip 104 has a substrate 120. The substrate 120 of the integrated circuit chip 104 can be virtually any type of material. Typically, the substrate 120 should be a material that can provide an adequate degree of structural rigidity to integrated circuit chip 104. The substrate 120 should also be a material suitable to provide some degree of protection to the integrated circuit. In a typical implementation, the substrate 120 of the integrated circuit chip 104 is silicon.

The substrate 120 of the integrated circuit chip 104 defines an internal cavity 122 in its upper surface that faces the radiation sensor chip 102. The internal cavity 122 is configured such that, when the integrated circuit chip 104 is physically coupled to the radiation sensor chip 102, as shown in FIG. 1A for example, the internal cavity 122 provides an empty space beneath (at least a portion of) the radiation sensing elements 114. This empty space helps ensure that the radiation sensing element 114 is adequately thermally isolated to facilitate its sensing functionalities.

An integrated circuit (not shown) is inside or physically coupled to the substrate 120. The integrated circuit can be virtually any kind of integrated circuit (e.g., a CMOS-based circuit) and be adapted, for example, to facilitate processing of electrical signals from the radiation sensor chip 102 and/or to interface to external circuit components (not shown). The integrated circuit can be an application specific integrated circuit (ASIC). In general, an ASIC is an integrated circuit that is customized for a particular use, rather than intended for general-purpose use.

Through-silicon vias 124 pass through the substrate 120 of the integrated circuit chip 104. The upper end 126 of each through-silicon via is exposed at an upper surface of the substrate 120 and bonded (e.g., by soldering or the like) to one of the electrically-conductive contacts 118 on the bottom surface of the radiation sensor chip 102. The through silicon vias are electrically coupled to integrated circuit, which is inside or coupled to the substrate 120 of the integrated circuit chip 104. In a typical implementation, the integrated circuit chip 104 will have two through-silicon vias per pixel (i.e., per radiation sensing element).

There are electrical connections 128 at a bottom surface of the integrated circuit chip 104. In a typical implementation, these electrical connections 128 would be physically and electrically coupled (e.g., by soldering or the like) to corresponding electrical contacts on a printed circuit board (not shown). The integrated circuit chip 104 is able to interface with external circuitry (e.g., on the printed circuit board or elsewhere) through the electrical connections 128. The electrical connections 128 can be virtually any kind of electrical connection (e.g., solder bumps or the like). In the illustrated example, just about the entire bottom surface of the sensor assembly 100 can be devoted to connections 128.

In a typical implementation, the integrated circuit chip 104 has an overall thickness (i.e., from top to bottom in the illustrated example) of about 0.3 mm (e.g., from about 0.2 mm to about 0.4 mm, or from about 0.25 mm to about 0.35 mm).

The optical element 106 is above the radiation sensor chip 102. The optical element can be virtually any kind of material that is at least substantially transmissive to whatever wavelength(s) of radiation the radiation-sensing element 114 is designed to sense. For example, in various implementations, the optical element can be or include a lens (e.g., a Fresnel lens or dome lens), can include optical filtering capabilities, it can include or be an opening, it may be coated or uncoated, it can include a cover with one or more apertures. It may be made of silicon or any other suitable material.

In a typical implementation, the optical element 106 has an overall thickness (i.e., from top to bottom in the illustrated example) of about 0.2 mm to 0.3 mm.

FIG. 1B, a cross-sectional, plan, schematic view of the sensor assembly in FIG. 1A, shows the relative size and layout of a pixel (i.e., the space occupied by the radiation-sensing element) relative to the overall footprint of the sensor assembly 100.

In a typical implementation, the footprint of the overall sensor assembly 100 is square or rectangular with each edge being between about 1.0 millimeter and 1.6 millimeters. In some instances, the edges can be smaller than 1.0 millimeter.

During operation, radiation (e.g., ambient infrared radiation or near infrared radiation, etc.) enters the sensor assembly 100 through the optical element 106, passes through the opening 110 in the radiation sensor chip 102, passes through the membrane 112 of the radiation sensor chip 102 and impinges on the radiation sensing element and absorber 114 on the bottom side of the membrane 112.

The radiation-sensing element and absorber 114 reacts to the impinging radiation to produce and electrical output signal that represents the impinging radiation. The electrical output signal appears across the electrically-conductive output contacts at the bottom of the radiation sensor chip 102 and is delivered to the integrated circuit in the integrated circuit chip 104 by the through-silicon vias 124.

In a typical implementation, the integrated circuit on the integrated circuit chip 104 processes any electrical signals it receives and interfaces, via the electrical connections 128 on its bottom surface with a printed circuit board, and external circuit elements either on the printed circuit board or elsewhere through the connections 128.

The implementation represented in FIGS. 1A and 1B (i.e., with a single radiation-sensing element and no aperture) provides a very large field of view for the radiation-sensing element sensor and can be used in a variety of applications including, for example, temperature measurements for an object (e.g., a human face or other body part) in a monitored space.

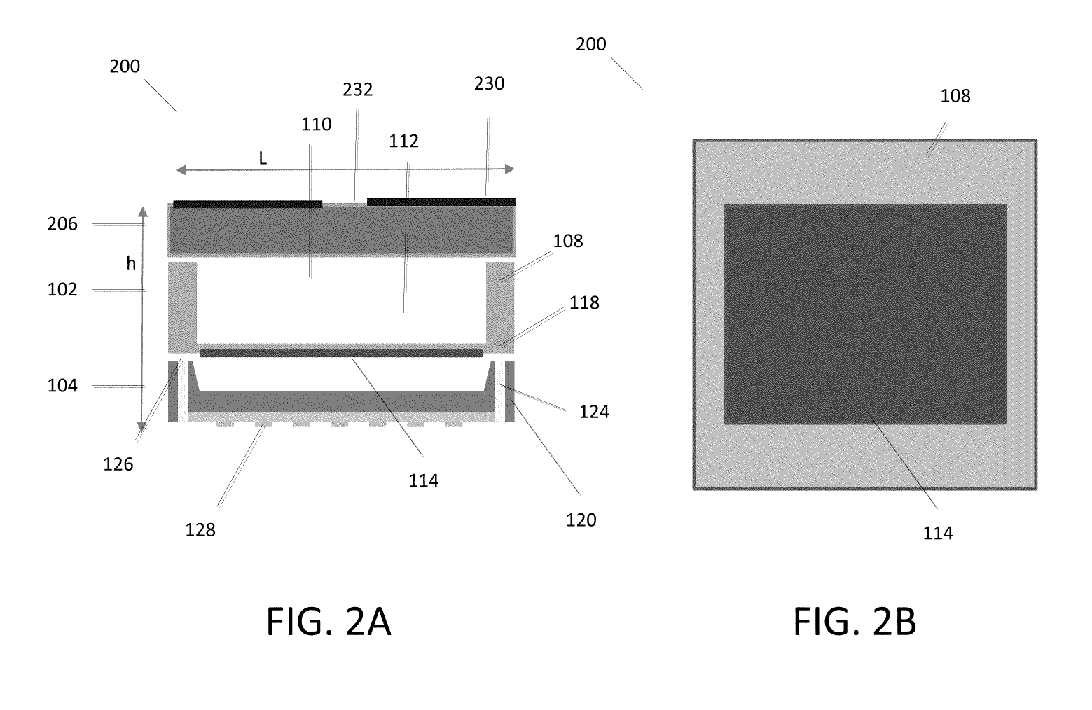

FIG. 2A shows a radiation sensor assembly 200 that is similar in many ways to the radiation sensor assembly 100 shown in FIG. 1A. For example, the radiation sensor assembly 200 in FIG. 2A includes, in a stacked configuration, a radiation sensor chip 102, an integrated circuit chip 104 beneath the radiation sensor chip 102 and an optical element 206 above the radiation sensor chip 102. Moreover, the radiation sensor chip 102, the integrated circuit chip 104 and the optical element 206 are substantially aligned with each other in a vertical direction. In the illustrated implementation, their respective outer edges are in alignment as well.

The main difference between the radiation sensor assembly 200 in FIG. 2A and the radiation sensor assembly 100 in FIG. 1A is that the optical element 206 in the radiation sensor assembly 200 of FIG. 2A has a cover 230 that defines an aperture 232. In a typical implementation, the cover 230 is made of a material that blocks or at least substantially blocks the passage of radiation that the radiation-sensing element can sense. The aperture 232 in the cover provides a limited field of view into the monitored space by the radiation sensor assembly 200.

FIG. 2B, a cross-sectional, plan, schematic view of the sensor assembly 200 in FIG. 2A, shows the relative size and layout of a pixel (i.e., the space occupied by the radiation-sensing element) relative to the overall footprint of the sensor assembly 200.

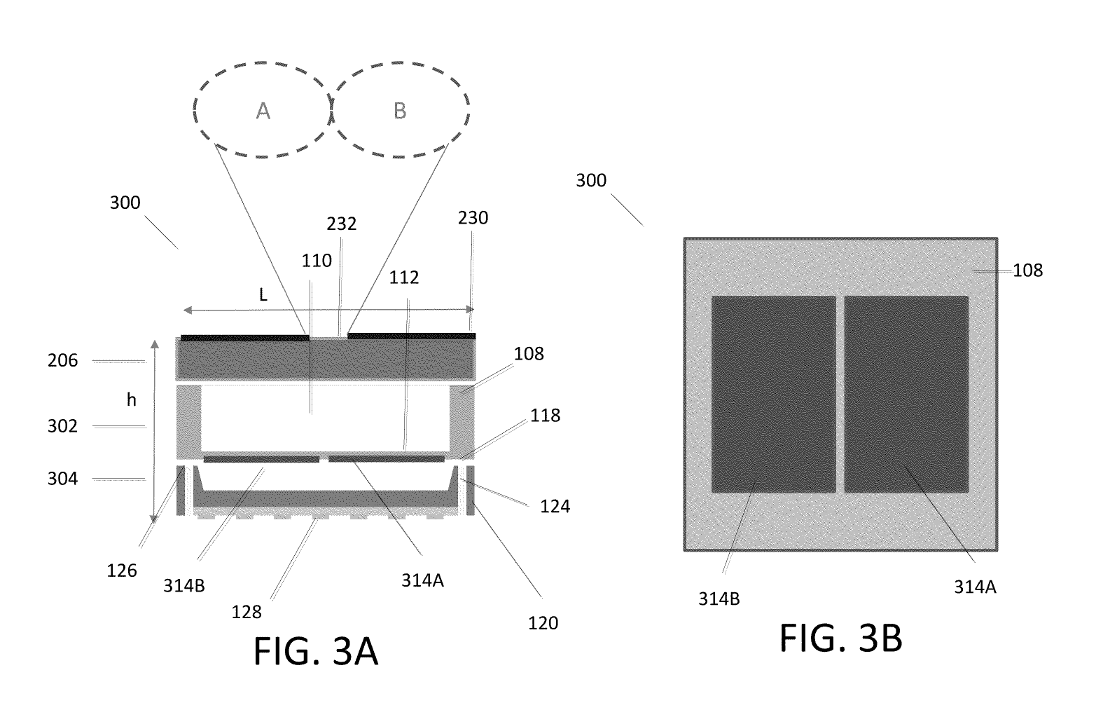

FIG. 3A shows a radiation sensor assembly 300 that is similar in many ways to the radiation sensor assembly 200 shown in FIG. 2A. For example, the radiation sensor assembly 300 in FIG. 3A includes, in a stacked configuration, a radiation sensor chip 302, an integrated circuit chip 304 beneath the radiation sensor chip 302 and an optical element 206 above the radiation sensor chip 302. The radiation sensor chip 302, the integrated circuit chip 304 and the optical element 206 are substantially aligned with each other in a vertical direction so that, for example, their respective outer edges are in alignment as well. Moreover, the optical element 206 has a cover 230 that defines an aperture 232.

The main difference between the radiation sensor assembly 300 in FIG. 3A and the radiation sensor assembly 200 in FIG. 2A is that the radiation sensing chip 302 in the radiation sensor assembly 300 of FIG. 3A has two radiation sensing elements 314a, 314b (e.g., two thermopiles, or two “pixels”), instead of just one. The two pixels are side-by-side on the lower surface of the membrane 112 and each occupies about the same amount of space on the membrane 112 as the other.

The illustrated configuration (with two pixels and the aperture) results in each pixel “looking into” a different portion of the monitored space. In particular, during operation, pixel 314a “looks” into the portion of the monitored space labeled “A” and pixel 314b “looks” into the portion of the monitored space labeled “B.” In a typical implementation, the radiation sensor assembly (e.g., the integrated circuit in the radiation sensor chip) may be configured to recognize and react to movement (e.g., representing various gestures or the like) between zone “A” and zone “B.”

In some implementations of the radiation sensor assembly 300 in FIG. 3A, the radiation sensor chip 302 has two electrically conductive contacts per pixel (for a total of four electrically conductive contacts) and the integrated circuit chip 304 also has two exposed electrical conductors per pixel (for a total of four exposed electrical conductors). As assembled, each of the four electrically conductive contacts on the radiation sensor chip 302 lines up with (and is physically and electrically connected to) a corresponding one of the four exposed electrical conductors on the integrated circuit chip 304.

FIG. 3B, a cross-sectional, plan, schematic view of the sensor assembly 300 in FIG. 3A, shows the relative size and layout of the two pixels (i.e., the space occupied by the two radiation-sensing elements) relative to the overall footprint of the sensor assembly 300.

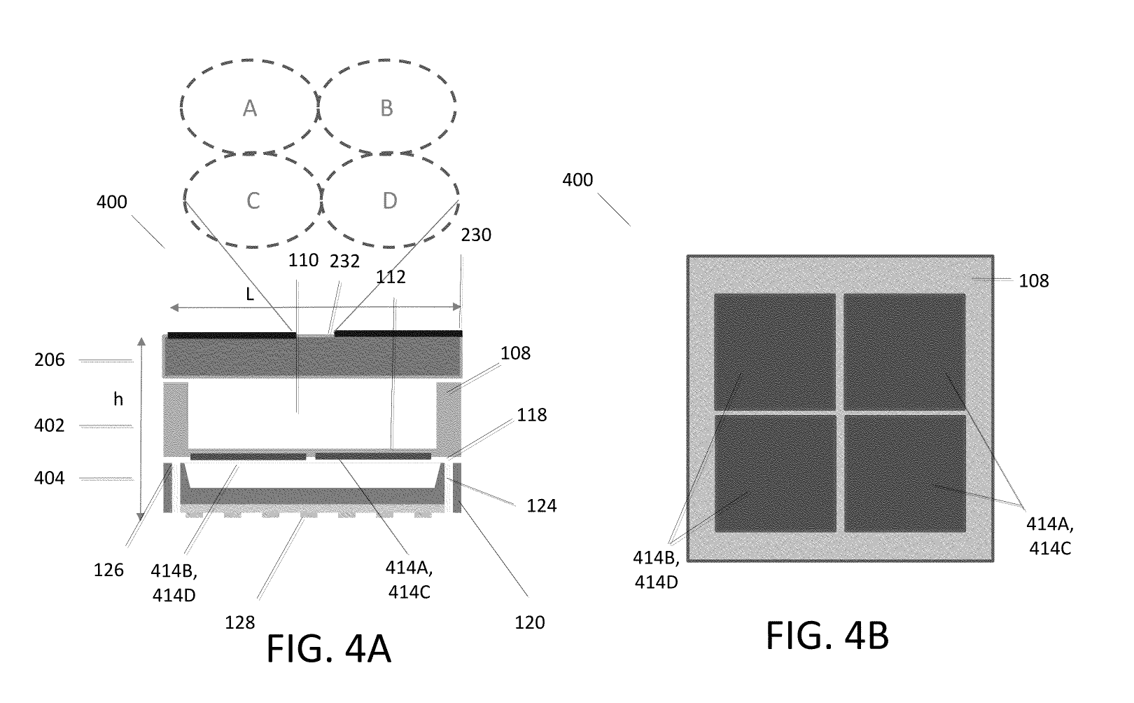

FIGS. 4A and 4B show a radiation sensor assembly 400 that is similar in many ways to the radiation sensor assembly 300 shown in FIGS. 3A and 3B, except the radiation sensor assembly 400 in FIGS. 4A and 4B has four pixels 414a-414d (e.g., four thermopiles), instead of only two. The four pixels 414a-414d are arranged in a 2×2 array, with each pixel being about the same size as the other pixels.

The illustrated configuration (with four pixels and the aperture) results in each pixel “looking into” a different portion of the monitored space. In particular, during operation, pixel 414a “looks” into the portion of the monitored space labeled “A,” pixel 414b “looks” into the portion of the monitored space labeled “B,” pixel 414c “looks” into the portion of the monitored space labeled “C” and pixel 414d “looks” into the portion of the monitored space labeled “D.” In a typical implementation, the radiation sensor assembly 400 (e.g., the integrated circuit in the radiation sensor chip) may be configured to recognize and react to movement (e.g., representing various gestures or the like) between zones A-D. Additionally, in some implementations, the radiation sensor assembly 400 can estimate speed and direction of movement.

In some implementations of the radiation sensor assembly 400 in FIGS. 4A and 4B, the radiation sensor chip 402 has two electrically conductive contacts per pixel (for a total of eight electrically conductive contacts) and the integrated circuit chip 404 also has two exposed electrical conductors per pixel (for a total of eight exposed electrical conductors). As assembled, each of the eight electrically conductive contacts on the radiation sensor chip 402 lines up with (and is physically and electrically connected to) a corresponding one of the eight exposed electrical conductors on the integrated circuit chip 404.

FIG. 4B, a cross-sectional, plan, schematic view of the sensor assembly 400 in FIG. 4A, shows the relative size and layout of the four pixels (i.e., the space occupied by the four radiation-sensing elements) relative to the overall footprint of the sensor assembly 400.

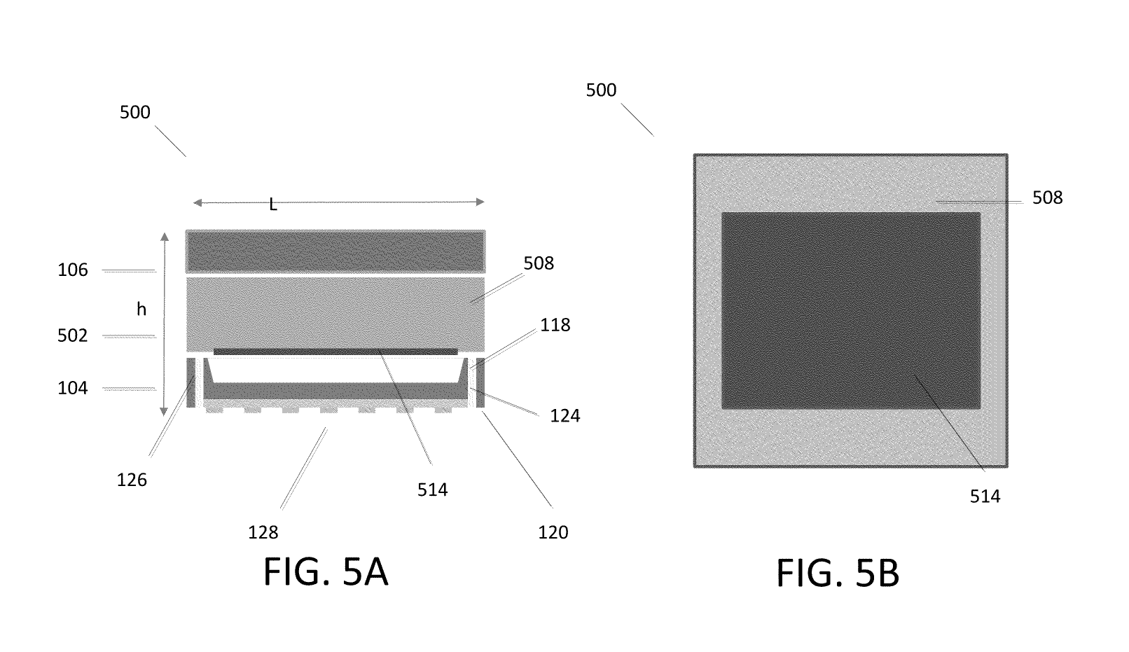

FIG. 5A shows a radiation sensor assembly 500 that is similar in many ways to the radiation sensor assembly 100 shown in FIG. 1A, except that the radiation sensor chip 502 in the radiation sensor assembly 500 of FIG. 5A has a substrate 508 that is cuboid (i.e., a solid with six rectangular faces at right angles to each other). In some implementations, the radiation sensor chip 502 (and/or the optical element 106) may be made of a material that limits (or that is dyed so that it limits) the radiation that is able to reach the radiation-sensing element 514 to only a certain range of wavelengths, including, typically, whatever wavelength(s) the radiation-sensing element is configured to sense. Moreover, in a typical implementation, the radiation-sensing element 514 on the bottom surface of the substrate 508 is a photo-diode.

FIG. 5B, a cross-sectional, plan, schematic view of the sensor assembly in FIG. 5A, shows the relative size and layout of a pixel (i.e., the space occupied by the radiation-sensing element) relative to the overall footprint of the sensor assembly 500.

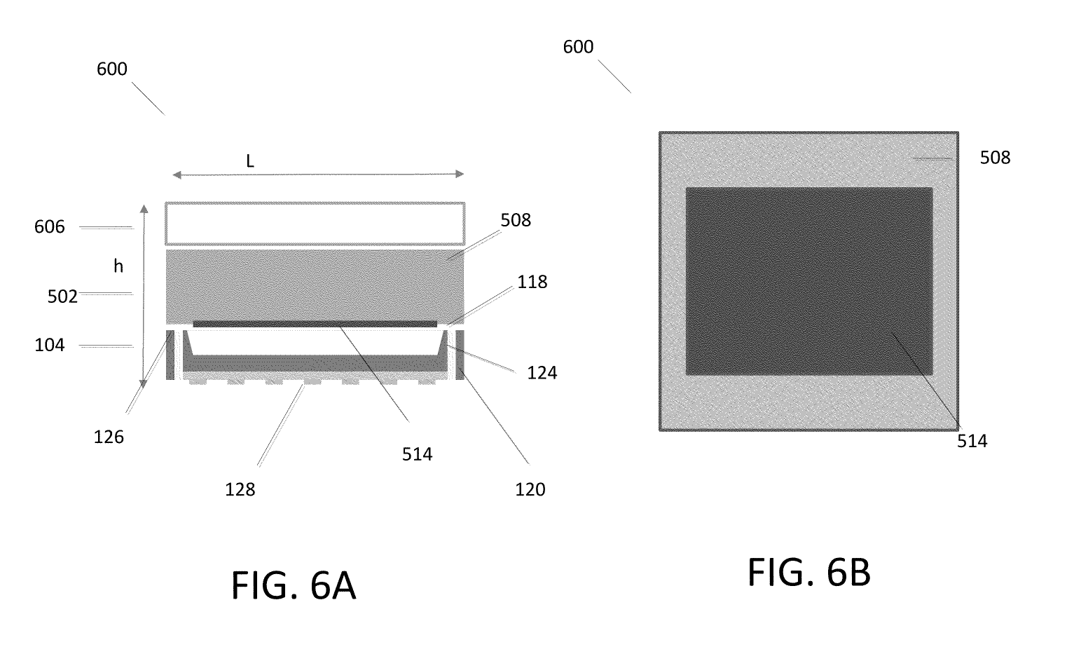

FIG. 6A shows a radiation sensor assembly 600 that is similar in many ways to the radiation sensor assembly 500 shown in FIG. 5A, except that the optical element 606 in the radiation sensor assembly 600 of FIG. 6A is not configured to limit the wavelengths of radiation that can pass through it. A typical implementation of the illustrated design provides for a large field of view for light measurements that may be used, for example, to sense presence.

FIG. 6B, a cross-sectional, plan, schematic view of the sensor assembly 600 in FIG. 6A, shows the relative size and layout of a pixel (i.e., the space occupied by the radiation-sensing element) relative to the overall footprint of the sensor assembly 600.

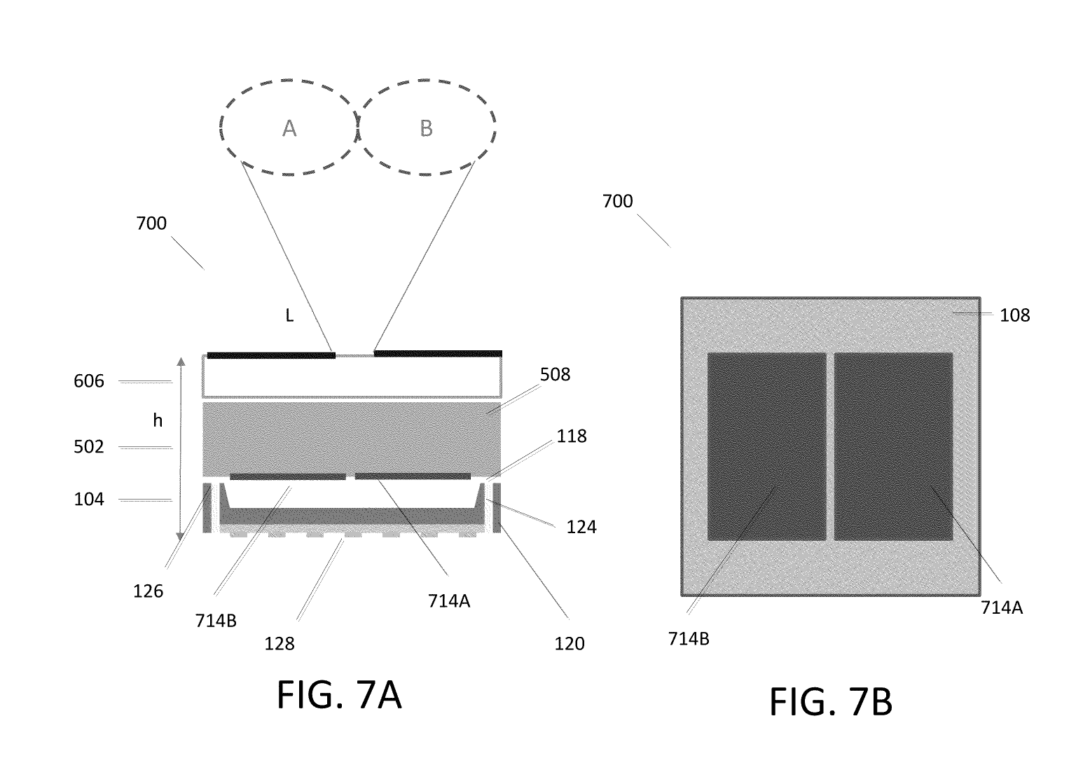

FIG. 7A shows a radiation sensor assembly 700 that is similar in many ways to the radiation sensor assembly 600 shown in FIG. 6A, except that the radiation sensor assembly 700 in FIG. 7A has two pixels (instead of only one) and the radiation sensor assembly 700 in FIG. 7A has a cover 730 that defines an aperture 732 that allows the passage of radiation into only certain parts of the optical element 706.

The two pixels are side-by-side on the lower surface of the substrate 508 of the radiation sensor chip 702 and each occupies about the same amount of space on the substrate 508 as the other.

The illustrated configuration (with two pixels and the aperture) results in each pixel “looking into” a different portion of the monitored space. In particular, during operation, pixel 714a “looks” into the portion of the monitored space labeled “A” and pixel 714b “looks” into the portion of the monitored space labeled “B.” In a typical implementation, the radiation sensor assembly (e.g., the integrated circuit in the radiation sensor chip) may be configured to recognize and react to movement (e.g., representing various gestures or the like) between zone “A” and zone “B.”

In some implementations, the radiation sensor chip 702 has two electrically conductive contacts per pixel (for a total of four electrically conductive contacts) and the integrated circuit chip 104 also has two exposed electrical conductors for connecting to the radiation sensor chip contacts per pixel (for a total of four exposed electrical conductors). As assembled, each of the four electrically conductive contacts on the radiation sensor chip 702 lines up with (and is physically and electrically connected to) a corresponding one of the four exposed electrical conductors on the integrated circuit chip 104.

FIG. 7B, a cross-sectional, plan, schematic view of the sensor assembly 700 in FIG. 7A, shows the relative size and layout of the two pixels (i.e., the space occupied by the two radiation-sensing elements) relative to the overall footprint of the sensor assembly 700.

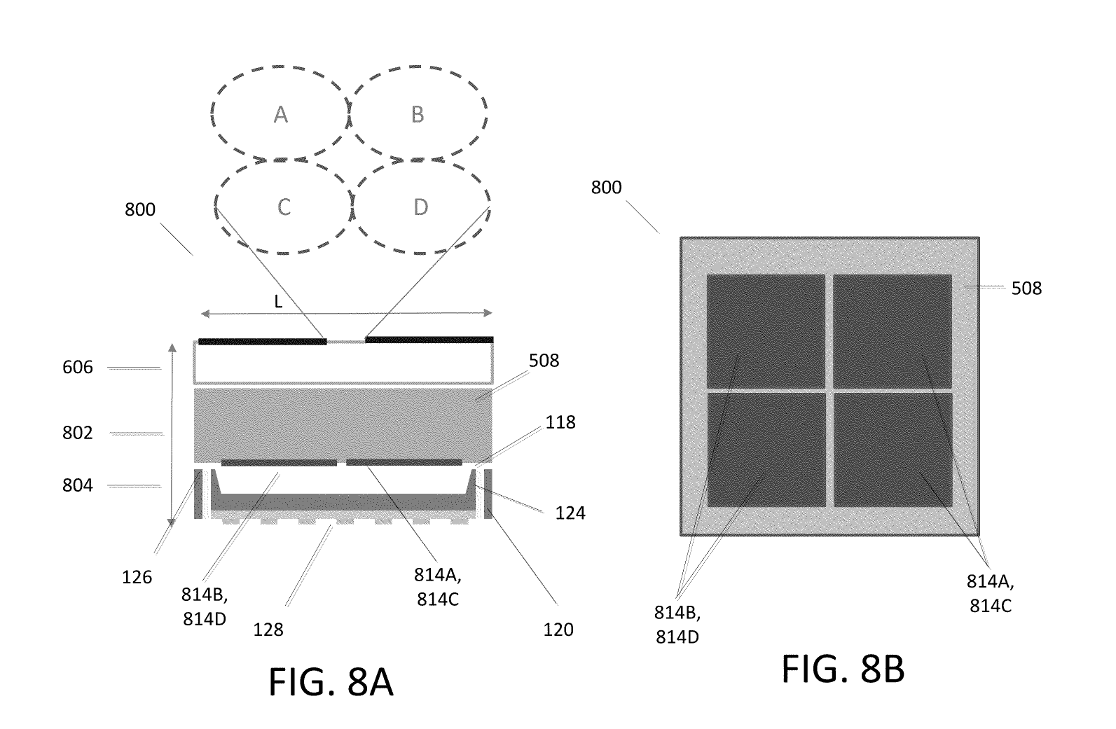

FIGS. 8A and 8B show a radiation sensor assembly 800 that is similar in many ways to the radiation sensor assembly 700 shown in FIGS. 7A and 7B. However, the radiation sensor chip 802 in the radiation sensor assembly 800 of FIGS. 8A and 8B has four pixels 814a-814d (e.g., four photo-diodes), instead of only two. The four pixels 814a-814d are arranged in a 2×2 array, with each pixel being about the same size as the other pixels. The radiation sensor chip 802 and the integrated circuit chip 804 have enough electrically conductive paths to accommodate the additional pixels.

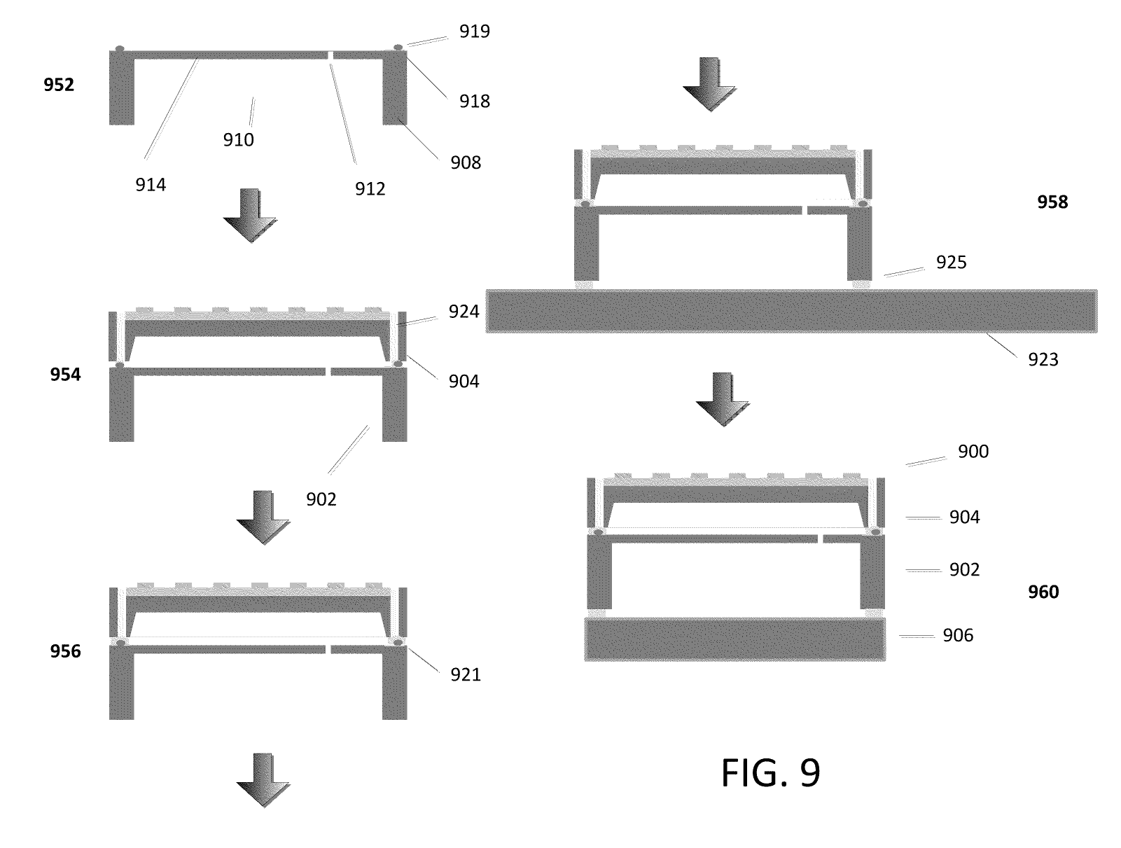

FIG. 9 is a series of cross-sectional views showing a radiation sensing apparatus at various stages of manufacture, according to one exemplary manufacturing process. As indicated, the exemplary manufacturing process results in a radiation sensing apparatus 900 that includes, in a vertically stacked configuration, an integrated circuit chip 904, a radiation sensor chip 902 (with, e.g., a thermopile 914), and an optical element 906.

The exemplary process includes providing, at step 952, a radiation sensor chip 902. The radiation sensor chip 902 is, in many ways, similar to the radiation sensor chip 102 described above and shown in FIGS. 1A and 1B. For example, the radiation sensor chip 902 has a radiation-sensing element, which is not shown in FIG. 9, but would be located on the upper surface of the radiation sensor chip 902, and a pair of electrically-conductive contacts 918 (e.g., pads) that are coupled to the radiation-sensing element and exposed at an outer, upper surface of the radiation sensor chip 902. Moreover, the radiation sensor chip 902 has a substrate 908 that defines a centrally-disposed opening 910 that extends through part of the substrate 908 and a membrane 912 that extends across the centrally-disposed opening 910 at the top of the opening 910. The radiation sensor chip 902 also has a cut or hole in the membrane 912 that helps avoid pressure issues during manufacturing and/or operation.

Next, the exemplary method includes coupling the radiation sensor chip 902 to an integrated circuit chip 904. The integrated circuit chip 904 is, in many ways, similar to the integrated circuit chip 104 described above and shown in FIGS. 1A and 1B. In particular, the integrated circuit chip 904 has an integrated circuit and a pair of electrical conductors 924 that are coupled to the integrated circuit and exposed at an outer, lower surface of the integrated circuit chip 904 that faces the outer surface of the radiation sensor chip 902.

According to the illustrated method, at step 952, a bonding substance (e.g., a solder bump 919, a silver epoxy dot, or the like) is deposited on each of the electrically-conductive contacts 918 on the radiation sensor chip 952. In some implementations, a second set of silver epoxy dots may be deposited on the electrically-conductive contacts 918 of the radiation sensor chip 918, as well.

Next, at step 954, the integrated circuit chip 904 is positioned as shown on top of the radiation sensor chip 902 with the lower, exposed portions of each electrical conductor 924 on the integrated circuit chip 904 in physical contact with one of the solder bumps 919 that was deposited on the electrically-conductive contacts 918 of the radiation sensor chip 918.

In step 956, the space between the bottom surface of the integrated circuit chip 904 (where the through-silicon vias are exposed) and the proximate upper surface of the radiation sensor chip 902 is filled with an epoxy 921 (e.g., an ultraviolet or heat curable epoxy). In a typical implementation, the epoxy is electrically non-conductive. The epoxy is cured by exposing it to ultraviolet radiation or heat, as applicable, which results in the radiation sensor chip 902 and the integrated circuit chip 904 being physically and electrically coupled to each other.

Next, at step 958, the combined radiation sensor chip 902 and integrated circuit chip 904 are placed on top of an optical element wafer 923, with a bead 925 of epoxy (e.g., an ultraviolet or heat curable epoxy) therebetween. More particularly, the combined radiation sensor chip 902 and integrated circuit chip 904 are placed so that the lower surface of the radiation sensor chip 902 will end up being physically bonded (by the epoxy) to the optical element wafer 923. Once the combined radiation sensor chip 902 and integrated circuit chip 904 are in place on the epoxy bead 925 above the optical element wafer 923, the epoxy bead 925 is cured.

In step 960, the wafer is diced to form a radiation sensing apparatus 900 that includes, in a vertically stacked configuration: a radiation sensor chip 902, an integrated circuit chip 904 on first side of the radiation sensor chip, and an optical element 906 on a second side of the radiation sensor chip (opposite the first side). As shown, in the resulting assembly 900, the radiation sensor chip 902, the integrated circuit chip 904 and the optical element 906 are vertically aligned such that every side edge of the radiation sensor chip lines up with a corresponding side edge of the integrated circuit chip and a corresponding side edge of the optical element.

In a typical implementation, the optical element wafer 923 (shown at step 958) will have an array of optical elements, each of which may be or include a lens (e.g., a Fresnel lens or dome lens), can include optical filtering capabilities, it may be coated or uncoated, it can include a cover with one or more apertures, It may be made of a silicon or any other suitable material. Thus, in a typical implementation of the illustrated method, multiple combined radiation sensor chip 902 and integrated circuit chip 904 sub-assemblies may be bonded to one single optical element wafer 923 and later diced.

The resulting radiation sensing apparatus 900 (and other radiation sensing apparatuses from the same wafer) can be tested (e.g., at step 958) before the wafer is diced or after the wafer is diced (e.g., after step 960).

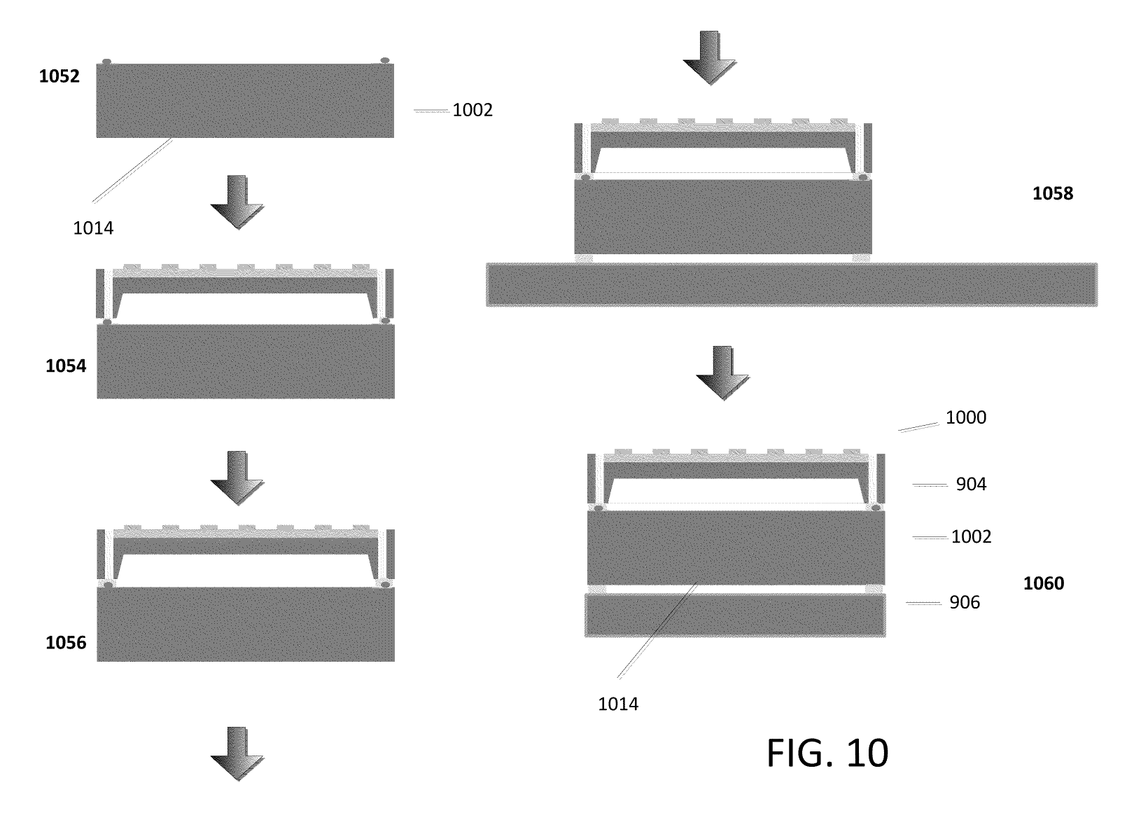

FIG. 10 is a series of cross-sectional views showing a radiation sensing apparatus 1000 at various stages of manufacture, according to one exemplary manufacturing process. The process represented in FIG. 10 is similar to the process represented in FIG. 9, except the radiation sensor chip 1002 in FIG. 10 has a photodiode 1014, instead of a thermopile 914. In FIG. 10, steps 1052-1060 respectively correspond to steps 952-960 in FIG. 9. The resulting structure 1000 is shown at 1060.

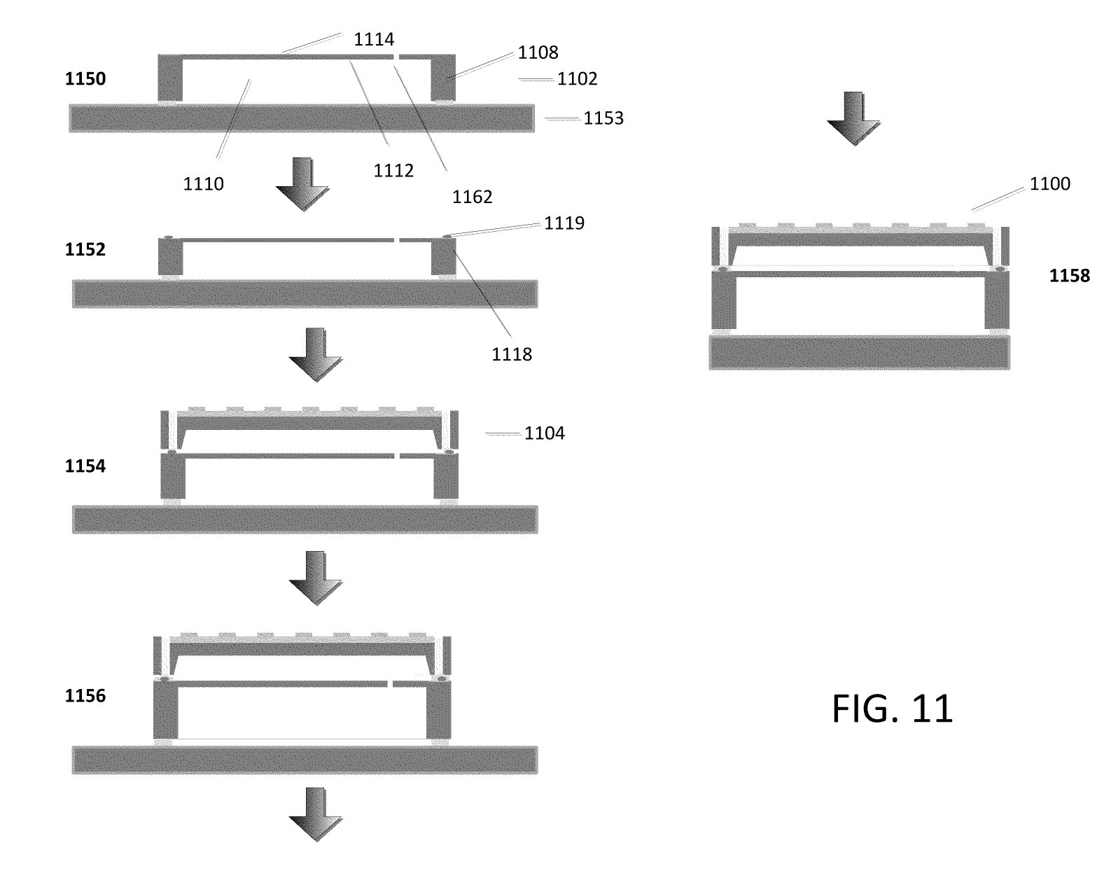

FIG. 11 is a series of cross-sectional views showing a radiation sensing apparatus 1100 at various stages of manufacture, according to one exemplary manufacturing process. As indicated, the exemplary manufacturing process results in a radiation sensing apparatus 1100 that includes, in a vertically stacked configuration, an integrated circuit chip 1104, a radiation sensor chip 1102 (with, e.g., a thermopile 1114), and an optical element 1106.

The exemplary process includes providing, at step 1150, a radiation sensor chip 1102. The radiation sensor chip 1102 is positioned on an optical filter wafer 1153 with a bead of ultraviolet or heat curable epoxy therebetween. The radiation sensor chip 1102 has a substrate 1108 and a membrane 1112 that extends across an opening 1110 in the substrate 1108. The radiation-sensing element (i.e., thermopile 1114) is on a top surface of the membrane 1112 in the configuration shown. There is a hole 1162 that extends through the membrane 1112. In a typical implementation, the hole 1162 in the membrane 1112 helps avoid pressure build-up during manufacturing or operation of the resulting assembly 1100.

At step 1152, a bonding substance (e.g., a solder bump 1119, a silver epoxy dot, or the like) is deposited on the electrically-conductive contacts 1118 on the radiation sensor chip 1102.

At step 1154, a second set of silver epoxy dots is deposited on the electrically-conductive contacts 1118 of the radiation sensor chip 1118, and the integrated circuit chip 1104 is positioned as shown above the radiation sensor chip 1152.

The space between the integrated circuit chip 1104 and the radiation sensor chip 1152 is underfilled and curing (e.g., ultraviolet or heat curing) occurs at 1156.

After step 1156, the resulting structure is diced to produce radiation sensing apparatus 1100. The radiation sensing apparatus 1100 can be tested before dicing (e.g., at 1156) or after dicing (e.g., at 1158).

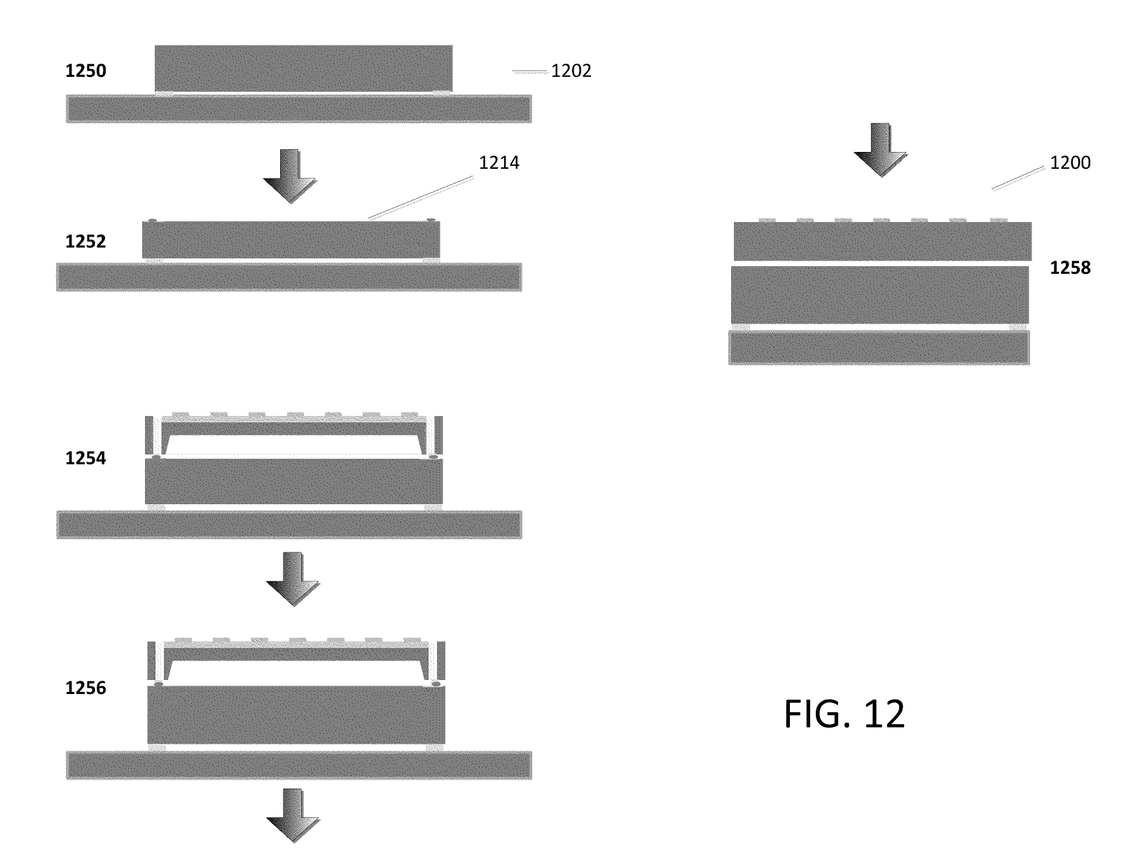

FIG. 12 is a series of cross-sectional views showing a radiation sensing apparatus 1200 at various stages of manufacture, according to one exemplary manufacturing process. The process represented in FIG. 12 is similar to the process represented in FIG. 11, except the radiation sensor chip 1202 in FIG. 12 is a solid structure (i.e., no opening and membrane) and has a photodiode 1214, instead of a thermopile 1114. In FIG. 12, steps 1250-1258 respectively correspond to steps 1150-1158 in FIG. 11. The resulting structure 1200 is shown at 1258.

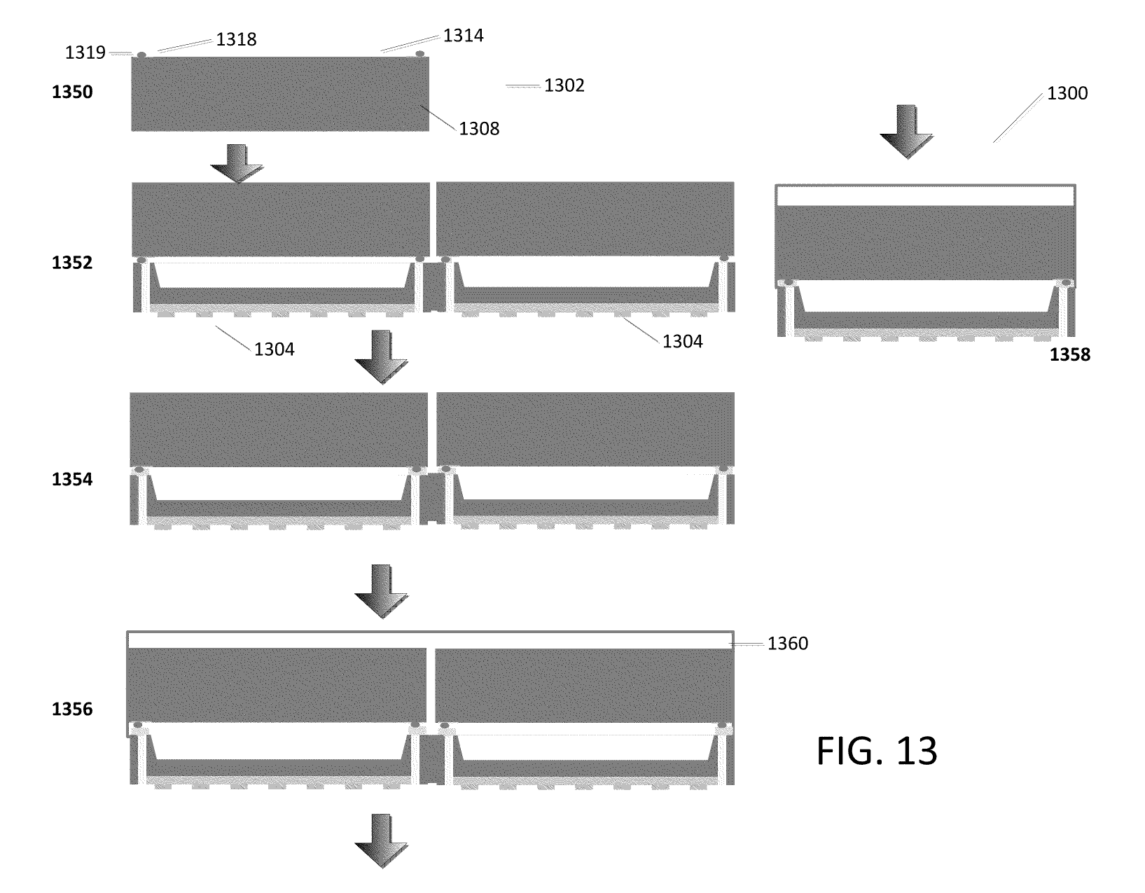

FIG. 13 is a series of cross-sectional views showing a radiation sensing apparatus 1300 at various stages of manufacture, according to one exemplary manufacturing process. As indicated, the exemplary manufacturing process results in a radiation sensing apparatus 1300 that includes, in a vertically stacked configuration, an integrated circuit chip 1304, a radiation sensor chip 1302 (with, e.g., a photodiode 1314), and an optical element 1306.

The exemplary process includes providing, at step 1350, a radiation sensor chip 1302. The radiation sensor chip 1302 has a photodiode 1314 and a pair of electrically conductive contacts 1318 on its upper surface. The substrate 1308 is solid and a material that is transmissive to whatever radiation the resulting assembly is intended to sense.

Solder bumps 1319 (or silver epoxy dots, or the like) are added to the electrically-conductive contacts 1318 at step 1350. In some implementations, a second set of solder bumps or silver epoxy dots are provided (e.g., at 1352) and then any bonding material is cured. Underfill is added and cured (e.g., by ultraviolet or heat curing) and the radiation sensor chip 1302 is positioned as shown to be connected to an integrated circuit chip 1304.

Then, in step 1356, the integrated circuit wafer/radiation sensor chip structure is covered with an epoxy 1360 (with or without added dye for optical wavelength filtering) to form the optical element. The epoxy is cured.

Then, in step 1358, the resulting wafer is diced and the resulting structure 1300 is tested.

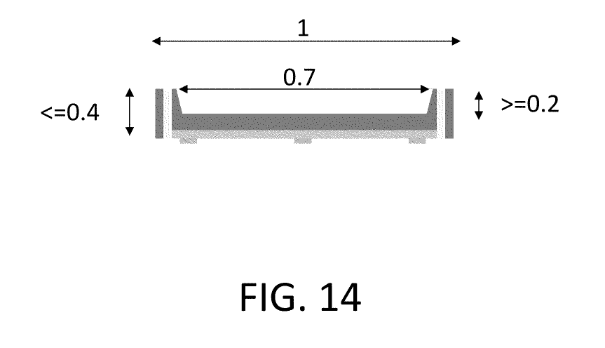

FIG. 14 is a schematic cross-sectional view of an exemplary integrated circuit chip with dimensions shown in millimeters.

A number of embodiments of the invention have been described. Nevertheless, it will be understood that various modifications may be made without departing from the spirit and scope of the invention.

For example, the size, shape and specific configuration of each of component (e.g., the radiation sensor chip, the integrated circuit chip, the optical element) described herein can be modified. Moreover, the specific configuration of the disclosed elements relative to each other can be modified to produce other stacking arrangements. For example, although certain arrangements have the outer edges of each component aligned with each other, in other arrangements, the outer edges do not align. Not only can the absolute sizes and shapes of the components be modified, but the relative sizes and shapes of the components and various parts of the components can be modified too. The methods of bonding, both physically and electrically, can be modified, thus resulting in a modified end structure.

The radiation-sensing element(s) can implement virtually any kind of sensing technology.

The processes described herein can be performed in a different order than what is described. In some implementations, additional steps may be performed and/or certain steps may be omitted. Moreover, in some implementations, some of the steps described may be omitted.

Different features described in connection with different implementations can be combined into other implementations. This applies to the structures disclosed as well as the processes disclosed.

Certain relative terminology is used herein, such as “above”, “beneath”, “upper”, “lower”, etc. This terminology is used for purposes of clarity and to describe the relative positions of certain objects in one exemplary orientation. It is not intended to limit the scope of what is disclosed or claimed, or to require that a structure have any particular orientation. Accordingly, such relative terminology should not be construed to limit the scope of the claims or what is disclosed.

The radiation sensor chip can utilize virtually any kind of radiation sensing technology. The integrated circuit chip can include virtually any kind of circuitry to process and/or pass information to and/or from the radiation sensor chip. The optical element can implement or be based upon virtually any kind of optical technology.

The various components can be vertically aligned relative to each other in a variety of ways. For example, in some implementations, one or more outer edges are aligned. However, that is not required. In a typical implementation, the components are aligned relative to the other components (e.g., chip(s)), in order ensure than the electrical contacts line up and make contact, and that the optical axis of the device and alignment are acceptable. The reference markers for that exact position might well be the edges of the chips, or other any other fiducial marking(s) or features on the components to assist alignment in the manufacturing line.

Other implementations are within the scope of the claims.

1. A radiation sensing apparatus comprising, in a vertically stacked configuration:
a radiation sensor chip comprising four or fewer thermopiles and an electrically-conductive contact coupled to the four or fewer thermopiles and exposed at a lower surface of the radiation sensor chip;
an integrated circuit chip beneath and coupled to the radiation sensor chip, the integrated circuit chip comprising an integrated circuit and an electrical conductor coupled to the integrated circuit and exposed at an upper surface of the integrated circuit chip facing the lower surface of the radiation sensor chip,
wherein the electrically conductive contact exposed at the lower surface of the radiation sensor chip is physically and electrically coupled to the electrical conductor exposed at the upper surface of the integrated circuit chip; and
an optical element above and coupled to the radiation sensor chip, wherein the optical element is transmissive to incident radiation at wavelengths from about 700 nanometers to about 1000 micron.

2. The apparatus of claim 1, wherein the radiation sensor chip, the integrated circuit chip and the optical element are vertically aligned with each other.

3. The apparatus of claim 1, wherein the electrically-conductive contact exposed at the lower surface of the radiation sensor chip is exposed near an outer perimeter of the radiation sensor chip,
wherein the electrical conductor exposed at the upper surface of the integrated circuit chip is exposed near an outer perimeter of the integrated circuit chip, and
wherein, during operation, radiation to be sensed passes through a space within outer perimeter of the radiation sensor chip to reach the radiation-sensing element.

4. The apparatus of claim 1, wherein:
the radiation sensor chip has a substrate that defines a centrally-disposed opening in the substrate that faces the optical element; and
a membrane extends across a lower end of the centrally-disposed opening in the substrate.

5. The apparatus of claim 4, wherein the radiation-sensing element is at least partially disposed on the membrane.

6. The apparatus of claim 5, wherein the radiation-sensing element is on a side of the membrane opposite the optical element, and the membrane is configured to pass radiation at the wavelength that the radiation-sensing element is configured to sense.

7. The apparatus of claim 6, wherein the integrated circuit chip has a substrate with a centrally-disposed cavity that opens toward the radiation sensor chip,
wherein the centrally-disposed cavity is configured to provide space around the radiation-sensing element when the integrated circuit chip is coupled to the radiation sensor chip to facilitate thermal isolation of at least a portion of the radiation-sensing element on the membrane.

8. The apparatus of claim 1, wherein the electrical conductor coupled to the integrated circuit and exposed at the outer surface of the integrated circuit chip comprises a through-silicon via.

9. The apparatus of claim 1, wherein the radiation-sensing element is selected from the group consisting of a thermopile and a photodiode.

10. The apparatus of claim 1, wherein the integrated circuit is an application-specific integrated circuit.

11. The apparatus of claim 1, wherein the optical element is a lens.

12. The apparatus of claim 1, wherein the radiation sensor chip comprises a plurality of radiation sensing elements.

13. The apparatus of claim 12, wherein the optical element comprises a cover with an aperture that restricts passage of radiation into part of the optical element.

14. The apparatus of claim 13, wherein the aperture and the plurality of radiation sensing elements are arranged such that, during operation, each respective one of the plurality of radiation sensing elements receives radiation through the aperture from a different part of a space being monitored than any of the other radiation sensing element.

15. (canceled)

16. The apparatus of claim 1, further comprising:
a plurality of electrically conductive pads exposed at a lower surface of the integrated circuit chip,
wherein the electrically conductive pads are configured to be physically and electrically bonded to corresponding conductive elements on a circuit board.

17. The apparatus of claim 1, wherein the radiation sensor chip, the integrated circuit chip and the optical element are configured such that:
when ambient radiation arrives at the optical element, at least part of the ambient radiation passes through the optical element and through a membrane that the radiation-sensing element is positioned upon to impinge upon the radiation-sensing element,
in response to the radiation impinging upon the radiation-sensing element, the radiation-sensing element produces an electrical output signal that corresponds to the impinging radiation,
the output signal is provided to the integrated circuit, and
the integrated circuit processes the output signal and interfaces with external circuit components.

18. A method of manufacturing a radiation sensing apparatus that includes, in a vertically stacked configuration, an integrated circuit chip, a radiation sensor chip, and an optical element, the method comprising:
providing a radiation sensor chip comprising four or fewer thermopiles and an electrically conductive contact coupled to the four or fewer thermopiles and exposed at an lower surface of the radiation sensor chip;
coupling the radiation sensor chip to an integrated circuit chip beneath the radiation sensor chip, the integrated circuit chip comprising an integrated circuit and an electrical conductor coupled to the integrated circuit and exposed at an upper surface of the integrated circuit chip facing the lower surface of the radiation sensor chip; and
coupling the radiation sensor chip to an optical element above the radiation sensor chip, wherein the optical element is transmissive to incident radiation at wavelengths from about 700 nanometers to about 1000 micron,
wherein coupling the radiation sensor chip to the integrated circuit chip comprises physically and electrically coupling the electrically conductive contact at the lower surface of the radiation sensor chip to the electrical conductor at the upper surface of the integrated circuit chip.

19. The method of claim 18, further comprising:
aligning the radiation sensor chip, the integrated circuit chip and the optical element in a vertical direction.

20. The method of claim 19, wherein the vertical alignment facilitates proper alignment of electrical contacts between the radiation sensor chip and the integrated circuit chip and of an optical axis.

21. The apparatus of claim 1, wherein the optical element comprises silicon.

22. The method of claim 18, wherein the optical element comprises silicon.
